(19) United States
(12) Patent Application Publication
(10) Pub. No.: US 2011/0155219 A1
(43) Pub. Date: Jun. 30, 2011

(54) THIN FILM SOLAR CELL AND METHOD FOR FABRICATING THE SAME

(75) Inventors: Jia-Wei Ma, Banqiao City (TW); Chan-Ching Chang, Longtan Township (TW); Yeong-Shyang Lee, Taipei City (TW); Hi-Ki Lam, Shatin (HK)

(73) Assignee: Du Pont Apollo Limited, Park Shek Kok (HK)

(21) Appl. No.: 12/965,919

(22) Filed: Dec. 12, 2010

Related U.S. Application Data
(60) Provisional application No. 61/290,638, filed on Dec. 29, 2009.

(51) Int. Cl. H01L 31/05; H01L 27/142

(52) U.S. Cl. 136/249; 438/80; 257/E27.123

(57) ABSTRACT

A thin film solar cell includes a substrate, a transparent electrode layer, a semiconductor layer, a back electrode layer, a positive electrode and a negative electrode. The semiconductor layer is formed on the transparent electrode layer and has grooves. The back electrode layer is formed on the semiconductor layer, in which formation of the semiconductor layer with the back electrode layer is patterned and the patterned formation with the transparent electrode layer form unit cells connected in series. The positive electrode is formed upon a front unit cell of the unit cells. The negative electrode is formed upon a last unit cell of the unit cells. The back electrode layer is formed to fill at least the grooves of the front unit cell and the last unit cell to directly connect with the transparent electrode layer. A method for fabricating a thin film solar cell is also provided.

### RELATED APPLICATIONS

This application claims priority to U.S. Provisional Application Ser. No. 61/290,638, filed Dec. 29, 2009, which is herein incorporated by reference.

### BACKGROUND

1. Technical Field

The present disclosure relates to a solar cell. More particularly, the present disclosure relates to an amorphous silicon semiconductor thin film solar cell.

2. Description of Related Art

Amorphous silicon (a-Si) semiconductor layers have been widely studied for use as a semiconductor layer for a solar cell, since they can be deposited uniformly in a large area onto a substrate at a low temperature by glow discharge decomposition of silane gas or the like and since various substrates such as glass, polymer films, ceramic plates, and metal foils may be used.

On the other hand, the amorphous silicon semiconductor's lower inherent efficiency is made up, at least partially, by their thinness, such that higher efficiencies can be reached by stacking several thin-film cells on top of each other and each of them is tuned to work well at a specific frequency of light. This approach is not applicable to crystalline silicon (c-Si) cells, which are thick as a result of their construction technique and are therefore largely opaque, blocking light from reaching other layers in a stack.

### SUMMARY

In accordance with one embodiment of the present invention, a thin film solar cell is provided. The thin film solar cell includes a substrate, a transparent electrode layer, a semiconductor layer, a back electrode layer, a positive electrode and a negative electrode. The transparent electrode layer is formed on the substrate. The semiconductor layer is formed on the transparent electrode layer and has grooves. The back electrode layer is formed on the semiconductor layer, in which formation of the semiconductor layer with the back electrode layer is patterned and the patterned formation with the transparent electrode layer form a plurality of unit cells connected in series. The positive electrode is formed upon a front unit cell of the series-connected unit cells to be a positive terminal electrode of the thin film solar cell. The negative electrode is formed upon a last unit cell of the series-connected unit cells to be a negative terminal electrode of the thin film solar cell. The back electrode layer is formed to fill at least the grooves of the front unit cell under the positive electrode and the last unit cell under the negative electrode to directly connect with the transparent electrode layer.

In accordance with another embodiment of the present invention, a method for fabricating a thin film solar cell is provided. The method includes the steps of: forming a transparent electrode layer on a substrate; forming a semiconductor layer on the transparent electrode layer; patterning the semiconductor layer to form a plurality of semiconductor regions and first grooves; forming a back electrode layer to cover the semiconductor regions and to fill the first grooves; patterning the back electrode layer to form a plurality of back electrodes such that the back electrodes, the semiconductor regions and the transparent electrode layer form a plurality of unit cells connected in series; forming a positive electrode upon a front unit cell of the series-connected unit cells to be a positive terminal electrode of the thin film solar cell; and forming a negative electrode upon a last unit cell of the series-connected unit cells to be a negative terminal electrode of the thin film solar cell; wherein the back electrode layer is formed such that the back electrode layer fills at least the first grooves of the front unit cell under the positive electrode and the last unit cell under the negative electrode to directly connect with the transparent electrode layer.

In accordance with yet another embodiment of the present invention, a method for fabricating a thin film solar cell is provided. The method includes the steps of: forming a transparent electrode layer on a substrate; laser-scribing the transparent electrode layer to form a plurality of transparent electrodes and first grooves; forming a semiconductor layer to cover the transparent electrodes and to fill the first grooves; laser-scribing the semiconductor layer to form a plurality of semiconductor regions and second grooves; forming a back electrode layer to cover the semiconductor regions and to fill the second grooves; laser-scribing the back electrode layer to form a plurality of back electrodes such that the back electrodes, the semiconductor regions and the transparent electrode layer form a plurality of unit cells connected in series; forming a positive electrode upon a front unit cell of the series-connected unit cells to be a positive terminal electrode of the thin film solar cell; and forming a negative electrode upon a last unit cell of the series-connected unit cells to be a negative terminal electrode of the thin film solar cell; wherein the back electrodes of the front unit cell and the last unit cell are formed to make direct ohmic contact with the corresponding transparent electrodes through the second grooves of the front unit cell under the positive electrode and the last unit cell under the negative electrode.

It is to be understood that both the foregoing general description and the following detailed description are by examples, and are intended to provide further explanation of the invention as claimed.

### BRIEF DESCRIPTION OF THE DRAWINGS

The disclosure can be more fully understood by reading the following detailed description of the embodiments, with reference to the accompanying drawings as follows:

FIG. 1 is a diagram of a thin film solar cell according to one embodiment of the present invention;

FIG. 2 through FIG. 7 illustrates a fabrication process of the thin film solar cell shown in FIG. 1 according to one embodiment of the present invention;

FIG. 8 illustrates the experimental data of thin film solar cells with different formations and under different conditions in one embodiment; and

FIG. 9 illustrates the experimental data of the thin film solar cells under different conditions in the other embodiment.

### DESCRIPTION OF THE EMBODIMENTS

In the following detailed description, the embodiments of the present invention have been shown and described. As will be realized, the disclosure is capable of modification in various respects, all without departing from the disclosure. Accordingly, the drawings and description are to be regarded as illustrative in nature, and not restrictive.

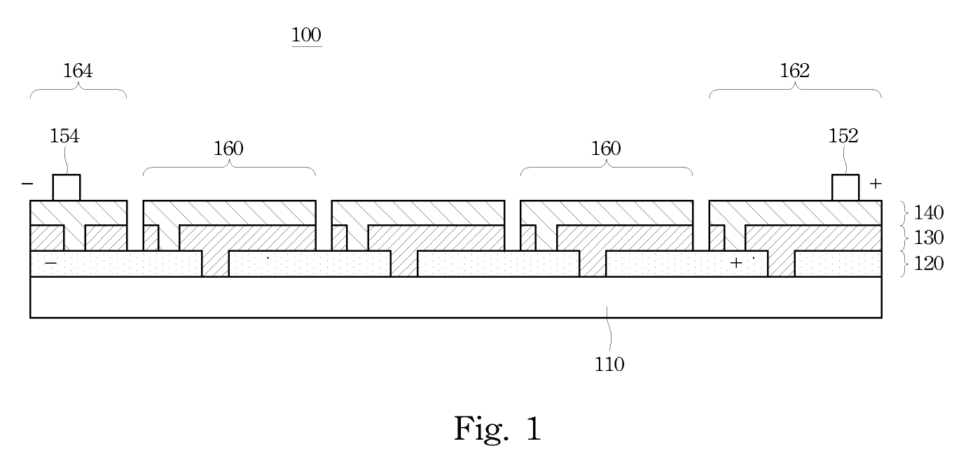

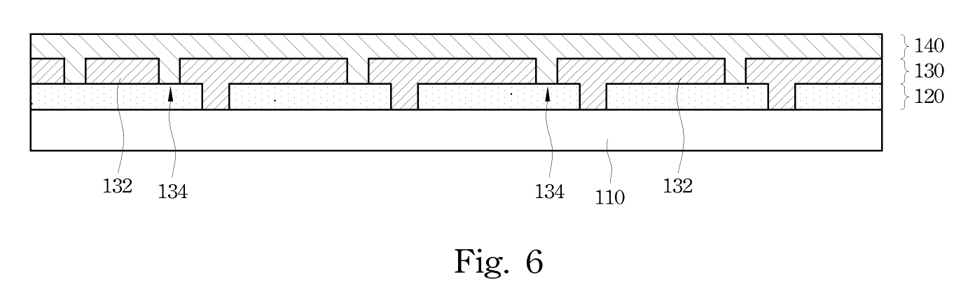

FIG. 1 is a diagram of a thin film solar cell according to one embodiment of the present invention. The thin film solar cell 100 includes a substrate 110, a transparent electrode layer 120, a semiconductor layer 130, a back electrode layer 140, a positive electrode 152 and a negative electrode 154. The transparent electrode layer 120 is formed on the substrate 110. The semiconductor layer 130 is formed on the transparent electrode layer 120 and has grooves (as shown in FIG. 5) defined therein. The back electrode layer 140 is formed on the semiconductor layer 130, in which formation of the semiconductor layer 130 with the back electrode layer 140 is patterned and the patterned formation with the transparent electrode layer 120 form a plurality of unit cells including a front unit cell 162, a last unit cell 164 and other unit cells 160 which are connected in series. The positive electrode 152 is formed upon the front unit cell 162 of the series-connected unit cells to be a positive terminal electrode of the thin film solar cell 100. The negative electrode 154 is formed upon the last unit cell 164 of the series-connected unit cells to be a negative terminal electrode of the thin film solar cell 100. The back electrode layer 140 is formed to fill at least the grooves (as shown in FIG. 6) of the front unit cell 162 under the positive electrode 152 and the last unit cell 164 under the negative electrode 154 to directly connect with the transparent electrode layer 120. In one embodiment, the back electrode layer 140 makes direct ohmic contact with the transparent electrode layer 120 through the grooves (as shown in FIG. 6) of the front unit cell 162 under the positive electrode 152 and the last unit cell 164 under the negative electrode 154. The fabrication process and formation of the thin film solar cell 100 are described as follows.

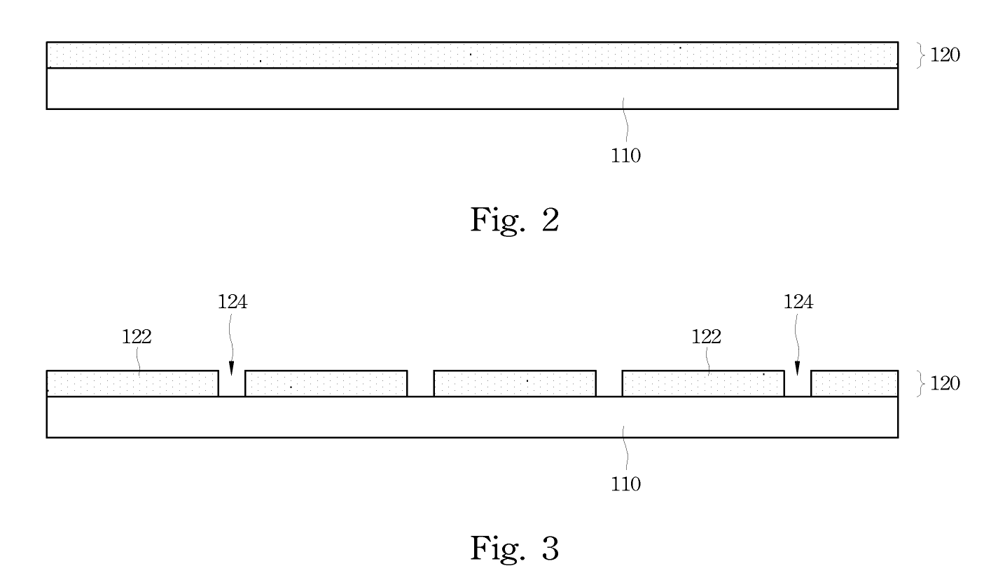

FIG. 2 through FIG. 7 illustrates a fabrication process of the thin film solar cell shown in FIG. 1 according to one embodiment of the present invention. First, the transparent electrode layer 120 is formed on the substrate 110 (as shown in FIG. 2), in which the transparent electrode layer 120 may include or be made of transparent conductive oxide. Then, the transparent electrode layer 120 is patterned to form a plurality of transparent electrodes 122 and grooves 124 (as shown in FIG. 3). For example, the transparent electrode layer 120 are laser-scribed such that the transparent electrodes 122 and the grooves 124 are formed, in which the laser-scribing manner is a shallow cut which does not cut through the whole formation and which provides a sufficient separation; for example, the laser scribing manner may be implemented by utilizing a YAG laser.

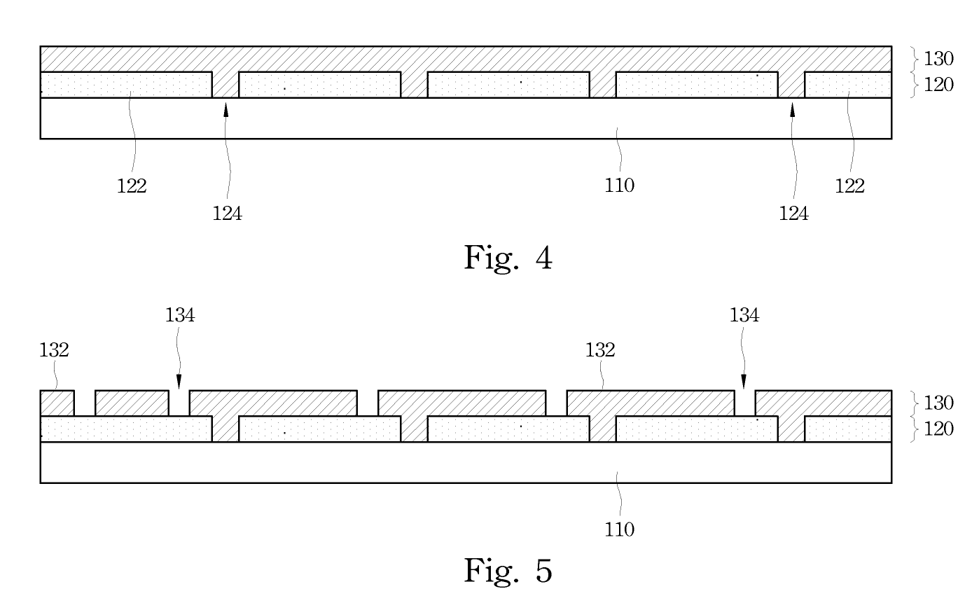

After that, the semiconductor layer 130 is formed on the transparent electrode layer 120 (as shown in FIG. 4) in which the semiconductor layer 130 may include or be made of amorphous silicon (a-Si). Specifically, the semiconductor layer 130 is formed to cover the transparent electrodes 122 and to fill the grooves 124. Then, the semiconductor layer 130 is patterned to form a plurality of semiconductor regions 132 and grooves 134 (as shown in FIG. 5). For example, the semiconductor layer 130 is laser-scribed such that the semiconductor regions 132 and the grooves 134 are formed. Also, the laser-scribing manner may be implemented by utilizing a YAG laser.

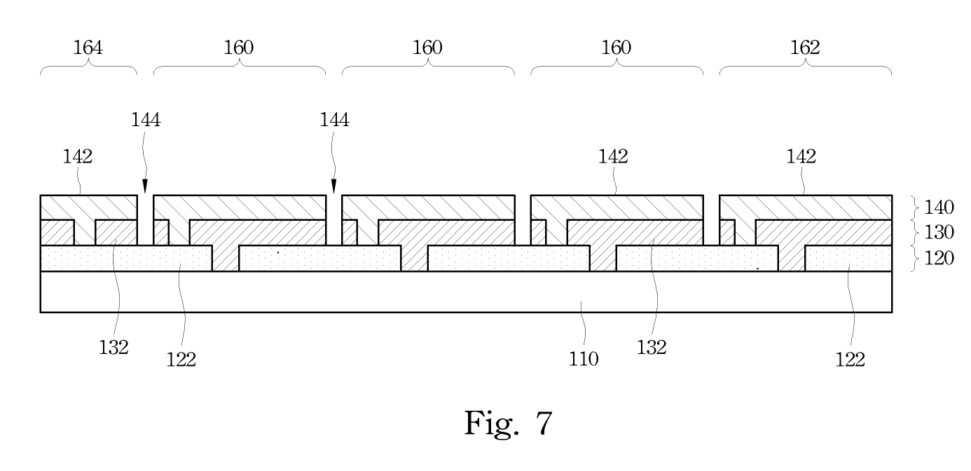

Thereafter, the back electrode layer 140 is formed on the semiconductor layer 130, and more specifically, the back electrode layer 140 is formed to cover the semiconductor regions 132 and to fill the grooves 134 (as shown in FIG. 6), in which the back electrode layer 140 may include or be made of metal, such as Ag, Al, etc., which generally has high light-reflective characteristic. Then, the back electrode layer 140 is patterned to form a plurality of back electrodes 142 such that the back electrodes 142, the semiconductor regions 132 and the transparent electrode 122 form the unit cells including the front unit cell 162, the last unit cell 164 and other unit cells 160 which are connected in series (as shown in FIG. 7). For example, the back electrode layer 140 also may be laser-scribed to form the back electrodes 142. Notably, the formations of the back electrode layer 140 and the semiconductor layer 130 including the semiconductor regions 132 shown in FIG. 6 are patterned at the same time, such that the back electrodes 142 and grooves 144 are formed and thus the unit cells 160, 162 and 164 are formed. As mentioned above, the back electrode 142 of one unit cell can thus be electrically connected to the transparent electrode 122 of the neighboring unit cell, thus forming the series-connected unit cells and obtaining a higher output voltage necessary for practical use.

Then, the positive electrode 152 is formed upon the front unit cell 162 of the series-connected unit cells to be a positive terminal electrode of the thin film solar cell 100, and the negative electrode 154 is formed upon the last unit cell 164 of the series-connected unit cells to be a negative terminal electrode of the thin film solar cell 100 (as shown in FIG. 1). For the positive electrode 152 and the negative electrode 154, they may be a metallic ribbon or strip-like electrodes with a predetermined width.

As shown in FIG. 1, the back electrode layer 140 is formed such that the back electrode layer 140 fills at least the grooves 134 (as shown in FIG. 6) of the front unit cell 162 under the positive electrode 152 and the last unit cell 164 under the negative electrode 154 to directly connect with the transparent electrode layer 120. In the present embodiment, the back electrodes 142 (as shown in FIG. 7) of the front unit cell 162 and the last unit cell 164 are formed to make direct ohmic contact with the transparent electrode layer 120 (or corresponding transparent electrode 122) through the grooves 134 of the front unit cell 162 under the positive electrode 152 and the last unit cell 164 under the negative electrode 154.

For the embodiment shown in FIG. 7, since the back electrodes 142 (as shown in FIG. 7) of the front unit cell 162 and the last unit cell 164 are formed to directly connect with the transparent electrode layer 120, or even to make direct ohmic contact with the transparent electrode layer 120 (or corresponding transparent electrode 122) through the grooves 134 of the front unit cell 162 under the positive electrode 152 and the last unit cell 164 under the negative electrode 154, the currents can thus be well conducted between the positive terminal and negative terminal of the thin film solar cell, such that the performance of the solar cell can be improved.

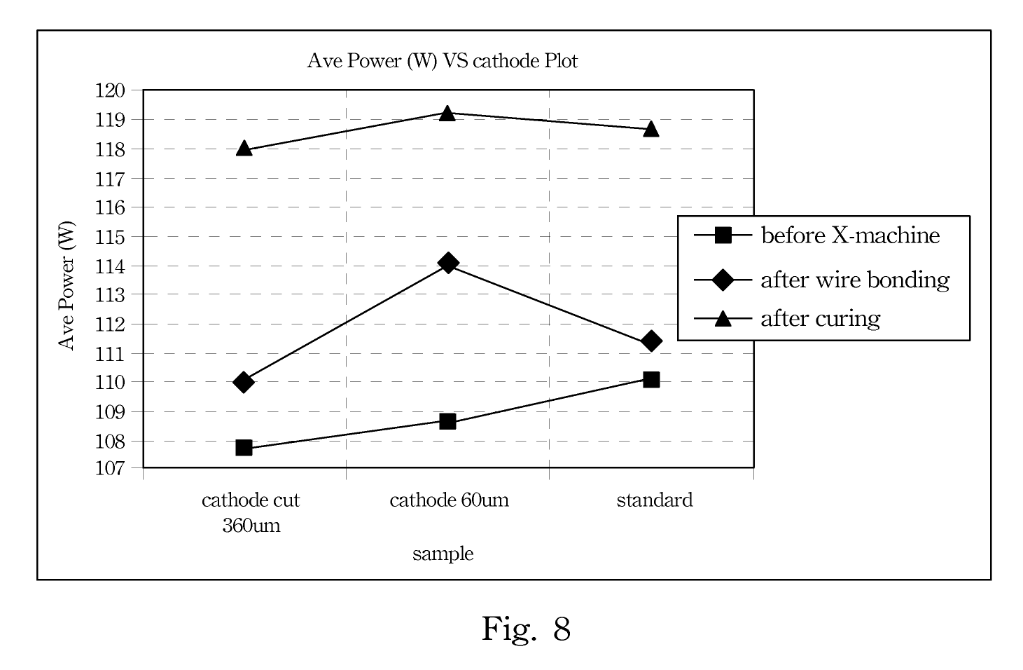

FIG. 8 illustrates the experimental data of thin film solar cells with different formations and under different conditions in one embodiment. As shown in FIG. 8, there are three types of samples, i.e. the standard sample (standard means traditional thin film solar cell without cathode cut), the sample having cathode width of about 60 um, and the sample having cathode cut width of about 360 um. According to the experimental data in FIG. 8, the sample having cathode cut width 360 um has similar power to the standard sample, and the sample having cathode cut width of about 360 um has slightly lower power than that of the sample having cathode width of about 60 um. Thus, the sample having cathode width of about 60 um is preferred above three of the samples.

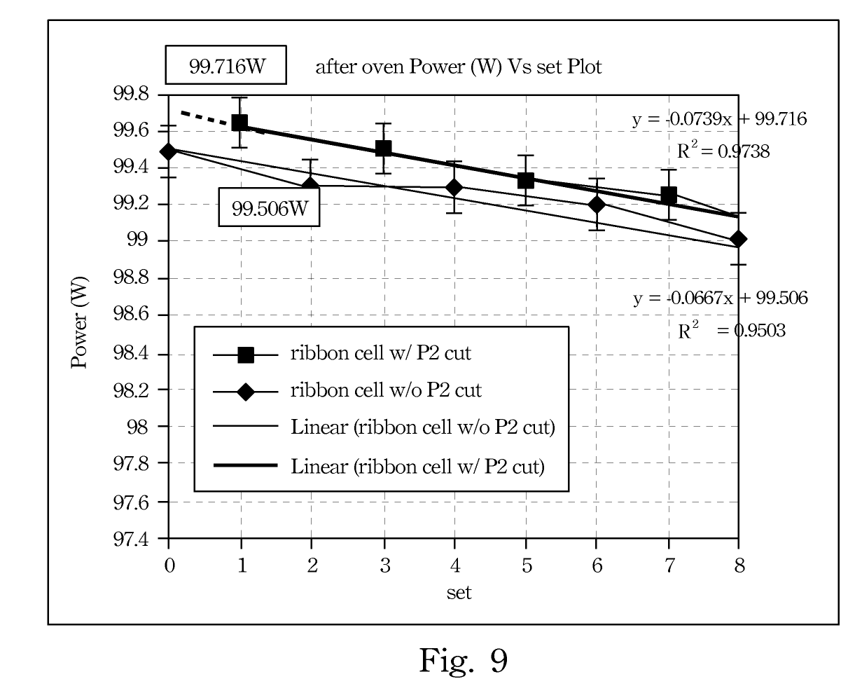

FIG. 9 illustrates the experimental data of the thin film solar cells under different conditions in the other embodiment. As shown in FIG. 9, there are two types of samples, i.e. the sample having cathode cut width of about 60 um, and the sample without cathode cut, in which ribbon cell w/P2_cut represents the sample having cathode cut width of about 60 um and ribbon cell w/o_P2_cut represents the sample having no cathode cut. According to the experimental data in FIG. 9, the sample having cathode cut width of about 60 um has greater power than the sample having no cathode cut. Thus, the present invention provides better power than traditional thin film solar cells.

As is understood by a person skilled in the art, the foregoing embodiments of the present invention are illustrative of the present invention rather than limiting of the present invention. It is intended to cover various modifications and similar arrangements included within the spirit and scope of the appended claims, the scope of which should be accorded with the broadest interpretation so as to encompass all such modifications and similar structures.

What is claimed is:

1. A thin film solar cell, comprising:
a substrate;
a transparent electrode layer formed on the substrate;
a semiconductor layer formed on the transparent electrode layer and having grooves;
a back electrode layer formed on the semiconductor layer, wherein formation of the semiconductor layer with the back electrode layer is patterned and the patterned formation with the transparent electrode layer form a plurality of unit cells connected in series;
a positive electrode formed upon a front unit cell of the series-connected unit cells to be a positive terminal electrode of the thin film solar cell; and
a negative electrode formed upon a last unit cell of the series-connected unit cells to be a negative terminal electrode of the thin film solar cell;
wherein the back electrode layer is formed to fill at least the grooves of the front unit cell under the positive electrode and the last unit cell under the negative electrode to directly connect with the transparent electrode layer.

2. The thin film solar cell as claimed in claim 1, wherein the back electrode layer makes direct ohmic contact with the transparent electrode layer through the grooves of the front unit cell under the positive electrode and the last unit cell under the negative electrode.

3. The thin film solar cell as claimed in claim 1, wherein the transparent electrode layer comprises transparent conductive oxide.

4. The thin film solar cell as claimed in claim 1, wherein the semiconductor layer comprises amorphous silicon.

5. The thin film solar cell as claimed in claim 1, wherein the back electrode layer comprises metal.

6. The thin film solar cell as claimed in claim 1, wherein the positive electrode and the negative electrode are formed to be ribbon electrodes.

7. A method for fabricating a thin film solar cell, comprising:
forming a transparent electrode layer on a substrate;
forming a semiconductor layer on the transparent electrode layer;
patterning the semiconductor layer to form a plurality of semiconductor regions and first grooves;
forming a back electrode layer to cover the semiconductor regions and to fill the first grooves;
patterning the back electrode layer to form a plurality of back electrodes such that the back electrodes, the semiconductor regions and the transparent electrode layer form a plurality of unit cells connected in series;
forming a positive electrode upon a front unit cell of the series-connected unit cells to be a positive terminal electrode of the thin film solar cell; and
forming a negative electrode upon a last unit cell of the series-connected unit cells to be a negative terminal electrode of the thin film solar cell;
wherein the back electrode layer is formed such that the back electrode layer fills at least the first grooves of the front unit cell under the positive electrode and the last unit cell under the negative electrode to directly connect with the transparent electrode layer.

8. The method as claimed in claim 7, further comprising:
patterning the transparent electrode layer to form a plurality of transparent electrodes and second grooves.

9. The method as claimed in claim 8, wherein the step of forming the semiconductor layer on the transparent electrode layer further comprises:
forming the semiconductor layer to cover the transparent electrodes and to fill the second grooves.

10. The method as claimed in claim 7, wherein the back electrodes of the front unit cell and the last unit cell are formed to make direct ohmic contact with the transparent electrode layer through the first grooves of the front unit cell under the positive electrode and the last unit cell under the negative electrode.

11. The method as claimed in claim 7, wherein the transparent electrode layer comprises transparent conductive oxide.

12. The method as claimed in claim 7, wherein the semiconductor layer comprises amorphous silicon.

13. The method as claimed in claim 7, wherein the back electrode layer comprises metal.

14. The method as claimed in claim 7, wherein the positive electrode and the negative electrode are formed to be ribbon electrodes.

15. A method for fabricating a thin film solar cell, comprising:
forming a transparent electrode layer on a substrate;
laser-scribing the transparent electrode layer to form a plurality of transparent electrodes and first grooves;
forming a semiconductor layer to cover the transparent electrodes and to fill the first grooves;
laser-scribing the semiconductor layer to form a plurality of semiconductor regions and second grooves;
forming a back electrode layer to cover the semiconductor regions and to fill the second grooves;
laser-scribing the back electrode layer to form a plurality of back electrodes such that the back electrodes, the semiconductor regions and the transparent electrode layer form a plurality of unit cells connected in series;
forming a positive electrode upon a front unit cell of the series-connected unit cells to be a positive terminal electrode of the thin film solar cell; and
forming a negative electrode upon a last unit cell of the series-connected unit cells to be a negative terminal electrode of the thin film solar cell;
wherein the back electrodes of the front unit cell and the last unit cell are formed to make direct ohmic contact with the corresponding transparent electrodes through the second grooves of the front unit cell under the positive electrode and the last unit cell under the negative electrode.

16. The method as claimed in claim 15, wherein the transparent electrode layer comprises transparent conductive oxide.

17. The method as claimed in claim 15, wherein the semiconductor layer comprises amorphous silicon.

18. The method as claimed in claim 15, wherein the back electrode layer comprises metal.

19. The method as claimed in claim 15, wherein the positive electrode and the negative electrode are formed to be ribbon electrodes.
